(19) United States
(12) Patent Application Publication
(10) Pub. No.: US 2024/0008219 A1
(43) Pub. Date: Jan. 4, 2024

(54) Power Module with an Insulated, Divided Heatsink, and Vehicle with a Power Module

(71) Applicant: Robert Bosch GmbH, Stuttgart (DE)

(72) Inventors: Paul Mehringer, Stuttgart (DE); Benedikt Scholz, Korntal (DE); Narcisse Fotso Simo, Reutlingen (DE); Marcus Mutschler, Pleidelsheim (DE)

(21) Appl. No.: 18/253,779

(22) PCT Filed: Nov. 24, 2021
(86) PCT No.: PCT/EP2021/082778

§ 371 Date: May 20, 2023

(30) Foreign Application Priority Data
Nov. 25, 2020 (DE) 10 2020 214 795.7

(51) Int. Cl. H05K 7/20; B60L 53/22

(52) U.S. Cl. CPC H05K 7/20254; H05K 7/20927; B60L 53/22

(57) ABSTRACT

A power module, in particular a drive module, is disclosed. The power module has a heatsink, in particular a cooling element, which is designed to conduct fluid, and at least two power components which are different from one another. The power components are each connected to the heatsink, in particular a part of the heatsink, in a thermally conductive or also electrically conductive manner. The power components are each designed to carry electric potentials, in particular ground potentials, which are different from one another. The heatsink comprises at least or only two parts, in particular one part and a further part which each have a cavity for conducting a fluid flow and which are connected to one another by way of an electrical insulator such that a fluid flow cooling both parts can flow through the parts. The parts are electrically insulated from one another such that the electric potentials of the power components are separated from one another within the heatsink.

### PRIOR ART

The invention relates to a power module, in particular a drive module. The power module has a heatsink, in particular a cooling element, which is designed to conduct fluid, and at least two power components which are different from one another. The power components are each connected to the heatsink, in particular a part of the heatsink, in a thermally conductive or also electrically conductive manner.

DE 197 56 250 C2 describes a self-commutated power converter of a voltage-impressing converter comprising high-power modules which are each detachably connected phase-wise to a phase heatsink and connected one above the other to a partition wall such that their cooling fins protrude through openings in this partition wall into a ventilation space.

DE 10 2010 041 589 A1 describes a housing for an electric machine, which can be coupled in a sealing manner to a housing element for receiving a power electronics of an electric machine.

### DISCLOSURE OF THE INVENTION

According to the invention, the power components are each designed to carry electric potentials, in particular ground potentials, which are different from one another. The heatsink comprises at least or only two parts, in particular one part and a further part which each have a cavity for conducting a fluid flow and which are connected to one another by means of an electrical insulator such that a fluid flow cooling both parts can flow through the parts, wherein the parts are electrically insulated from one another such that the electric potentials of the power components are separated from one another within the heatsink. Further advantageously, in this way, no current, in particular a mass flow, can flow over the parts of the heatsink which, for example, are made of aluminum. Further advantageously, no corrosion, in particular electrocorrosion, for example as a result of electrolysis, can occur as a result of such a mass flow at an in particular water-carrying cooling element.

The power module is preferably a drive module for a motor vehicle, in particular an electric vehicle or a hybrid vehicle. An inverter ground can advantageously be galvanically isolated or sufficiently insulated from the ground of the electric machine of the drive. Further advantageously, in this way, no ground loops that cause electrocorrosion can be formed, because a ground path on the heatsink is interrupted by the parts of the heatsink that are insulated from one another.

The parts of the heatsink are preferably each formed by a housing part, preferably an aluminum housing part, wherein the housing parts are connected to one another, in particular separably, and enclose the insulating layer between them. The heatsink can advantageously be configured to electrically insulate the power components from one another.

Preferably, one part of the heatsink is connected to a housing of a power component, in particular an electric machine, and the other part of the heatsink is connected to a further power component, in particular an inverter, or a housing of the further power component. The ground potentials of the power components can thus advantageously be separated from one another.

In an advantageous embodiment, the further part of the heatsink is coupled to a machine housing of the machine in an electrically isolated manner by means of the insulating element as an intermediate piece. For this purpose, a coupling surface of the coupling to the machine housing can extend on an end face, and thus transverse to a motor shaft, or be coupled to a housing side and thus disposed parallel to the motor shaft. Such an inverter can advantageously be coupled close to an electric machine and insulated from its housing.

The heatsink is preferably made of metal, in particular aluminum or copper.

The heatsink can thus advantageously have good thermal conductivity.

In a preferred embodiment of the power module, the insulator is formed by an in particular flat electrical insulating element or an electrically insulating layer, which is contacted by the parts and is enclosed between said parts, in particular in the manner of a sandwich.

The power module can thus advantageously be constructed in a compact manner, wherein the power components are each connected to the same heatsink, in particular the cooling element, in a thermally conductive manner.

In a preferred embodiment, the power components are each coupled to a fluid channel in a thermally conductive manner, wherein the fluid channels are fluidically connected to one another, in particular within the heatsink, preferably a housing which is formed by the heatsink and encloses a cavity. The cooling element can thus advantageously be provided in a space-saving and cost-efficient manner and can provide high electrical insulation resistance between the voltage-carrying parts.

In a preferred embodiment, one part of the cooling element comprises an inlet for the fluid and the other part of the cooling element comprises an outlet for the fluid. The fluid channels are each connected, in particular fluidically connected, to one another by means of a passage in the insulator, in particular within the cooling element. The only electrical connection between the parts of the cooling element can thus advantageously be formed via an in particular electrically conductive fluid, for example cooling water. The remaining parts, in particular the part and the other part of the cooling element, are electrically insulated from one another by means of the electrical insulator.

In a preferred embodiment, the passage comprises a passage opening, the cross-sectional area of which transverse to a flow direction of the fluid flow is smaller than a contact surface of the parts separated by the insulator. The electrical insulation resistance can thus advantageously be limited to a small passage opening which carries the fluid, in particular cooling water.

In a preferred embodiment, the insulator is formed by an insulating element. Further preferably, at least one or only one pin, which encloses the opening and extends into a part of the heatsink, in particular the machine housing of an electric machine or the cooling element of an inverter, is formed on the electrical insulating element. The fluid channel section insulated in the opening by the electrical insulating element can thus advantageously be electrically insulated from the one part. Further preferably, the insulating element comprises two pins formed on the electrical insulating element, which each extend into a part of the heatsink, in particular the cooling element of the inverter or the machine housing. The fluid channel section formed in the opening can thus advantageously be electrically insulated from the other part.

In the region of the opening, the insulating element can thus advantageously provide an insulating section which is longer than a thickness dimension of the insulating element and by means of which the parts of the heatsink are electrically insulated from one another.

The opening is preferably cylindrical. In this embodiment, the pin is hollow cylindrical. In another embodiment, the opening can have a polygonal cross-section. The pin can advantageously be formed on the insulator, in particular the insulating element.

In a preferred embodiment, the insulator is formed by a plastic layer. In a preferred embodiment, the insulator is an in particular temperature-resistant thermoplastic. The insulator can thus advantageously be adapted to fit snugly against the contact surfaces of the parts.

The plastic layer is a polyethylene layer, polypropylene layer, PEEK layer (PEEK=polyetheretherketone), PES layer (PES=polyethersulfone) or PPS layer (PPS=polyphenylene sulfide) or polyimide layer, for example. The insulator can thus advantageously be cost-efficiently provided as a solid body.

In another embodiment, the insulator is made of a silicone rubber. The insulator can thus advantageously also have a sealing function for the passage in addition to an insulating function. In this embodiment example, the insulator is disposed and configured such that it surrounds the passage.

In a preferred embodiment, the fluid is polar. The fluid is preferably an aqueous fluid. The fluid can thus advantageously be provided in a cost-efficient manner and have a good heat capacity. The fluid preferably comprises water and a glycol, in particular diethylene glycol. The fluid can thus advantageously be protected against freezing.

In another embodiment, the fluid is electrically insulating. In this embodiment, the fluid is made of an oil or an ester, in particular pentaerythritol ester, for example. Thus, advantageously, no current can flow between the parts of the heatsink, in particular housing parts of the cooling element, even in the region of the opening.

The power module preferably comprises a conductance sensor or resistance sensor, which is configured to detect an electrical conductance produced by the fluid or electrical contact resistance between the parts. A leakage current which flows through the fluid from the part of the cooling element to the other part of the cooling element can thus advantageously be detected.

The resistance sensor is preferably configured to produce an output signal which represents the electrical resistance between the parts. Preferably, an error signal can be produced as a function of the output signal, for example by a control unit of the electric machine. The control unit can provide the error signal on a data bus, for example.

The invention also relates to an electric vehicle or hybrid vehicle comprising a power module of the previously described type. The vehicle comprises an electric machine for driving the vehicle and an inverter. In the vehicle, one part of the cooling element is electrically connected to the inverter and the other part is electrically connected to the electric machine.

The power component is preferably formed by the inverter, and the further power component is preferably formed by the electric machine. Both the inverter and the electric machine can thus advantageously be cooled by the same cooling element.

In a preferred embodiment, the part of the heatsink is connected to a ground potential of the inverter and the other part of the heatsink is connected the ground potential of the electric machine. In this way, aside from a contact resistance formed by the cooling water, the ground potential of the inverter can advantageously be electrically insulated from the ground potential of the electric machine by means of the insulation layer and the thus configured power module.

The invention will be described in the following with reference to figures and further embodiment examples. Further advantageous design variants will emerge from a combination of the features described in the figures and in the dependent claims.

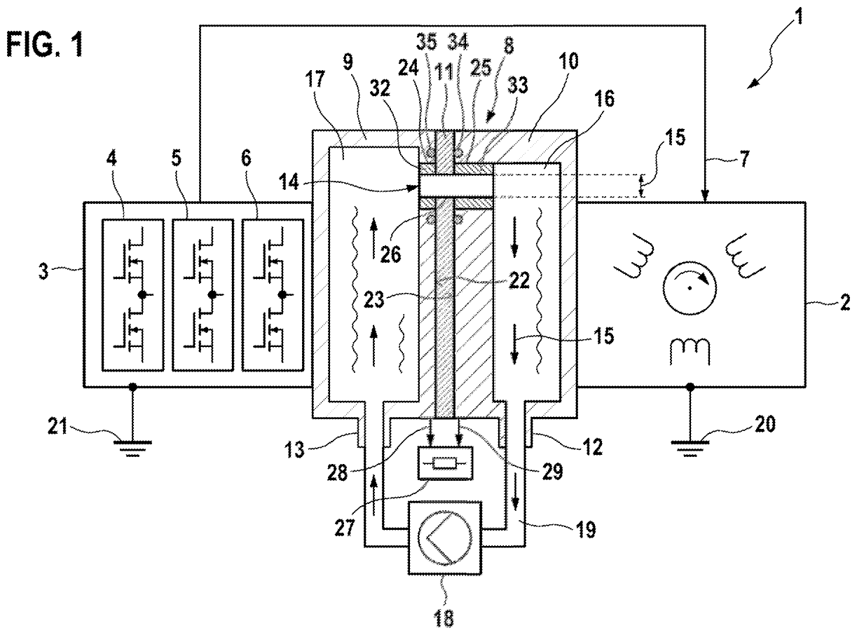

FIG. 1 shows an embodiment example using a drive module comprising an electric machine and an inverter for energizing the machine, wherein a machine housing and the inverter are both coupled to a heatsink and can be cooled by a fluid.

FIG. 1, schematically, shows an embodiment example using a drive module 1 in a sectional view. The drive module 1 comprises an electric machine 2 and an inverter 3. The inverter 3 is configured to energize the electric machine 2—in particular to produce a rotating magnetic field. In this embodiment example, the inverter 3 comprises three semiconductor switch half-bridges 4, 5 and 6, which are each configured to produce a pulse-modulated current for operating the machine 2. The semiconductor switch half-bridges 4, 5, and 6 are each configured to produce waste heat.

The drive module 1 also comprises a heatsink 8, which in this embodiment example is in the form of a cooling element configured to conduct fluid. The heatsink 8 is connected to the inverter 3, in particular the semiconductor switch half-bridges 4, 5 and 6, in a thermally conductive manner and is configured to absorb waste heat produced by the inverter 3. The heatsink 8 is also connected to the electric machine 2 in a thermally conductive manner and is configured to absorb waste heat from the electric machine 2.

In this embodiment example, the heatsink 8 comprises two parts which are joined together to form a one-piece heatsink 8, namely a part 9, which is connected to the inverter 3 in a thermally conductive and electrically conductive manner, and another part 10, which is connected to the electric machine 2 in a thermally conductive and electrically conductive manner. In this embodiment example, the parts 9 and 10 are both made of aluminum or copper and are thus both electrically conductive, so that the part 9 of the heatsink can carry a ground potential 21 of the inverter and the other part 10 can carry a ground potential 20 of the electric machine.

The part 9 and the other part 10 each enclose a cavity, which is configured to conduct a fluid flow 15. The cavities 16 and 17 each form a fluid channel in which the fluid flow 15 can flow and can absorb waste heat from the power components 2 and 3.

For this purpose, the part 9 encloses a cavity 17. In this embodiment example, the parts 9 and 10 are each formed by an aluminum housing which encloses the cavity 17 or 16. The other part 10 can be a part of a housing of the electric machine 2. The cavities 16 and 17 each form a fluid channel in which the fluid flow 15 can flow and can absorb waste heat from the power components 2 and 3.

The other part 10 comprises a coupling surface 23 for mechanical and thermally conductive coupling to the part 9. The part 9 comprises a coupling surface 22 for mechanical and thermally conductive coupling to the other part 10. The thermal contact surfaces 22 and 23 are each electrically insulated from one another by an electrical insulator, in this embodiment example of an electrical insulating element 11, and are connected in a thermally conductive manner. The electric insulating element 11 in this embodiment example is configured to be thermally conductive. The electrical insulating element 11 is formed by a plastic layer, in particular a thermoplastic layer, or a plastic plate, for example.

The cavities 17 and 16 enclosed by the parts of the heatsink, in particular the part 9 and the other part 10, are fluidically connected to one another by means of an opening 14 which forms a passage. For this purpose, the part 9 comprises a through-opening 24, which is opposite to a through-opening 25 of the other part 10.

The electrical insulating element 11 comprises an opening 26, which is enclosed between the through-openings 24 and 25. This creates a continuous opening 14, which in this embodiment example comprises an opening surface 15.

An opening volume of the opening 14 can thus conduct a quantity of cooling water, which can reduce an electrical insulation resistance between the part 9 and the other part 10 of the heatsink 8. The opening 14, in particular an opening surface 15 of the opening 14, is thus advantageously small enough that an electrical contact resistance between the parts 9 and 10 can limit a leakage current flowing there to less than 200 milliamperes.

FIG. 1 also shows a variant of the drive module, in which a pin 33, which encloses the opening 14 and extends into the part 10, in particular the machine housing, is formed on the electrical insulating element 11, so that the fluid channel section insulated in the opening by the electrical insulating element is electrically insulated from the part 10. In this variant, the insulating element also comprises a pin 32, which is formed on the electrical insulating element 11 and extends into the part 9, in particular the cooling element of the inverter 3, so that the fluid channel section formed in the opening 14 is electrically insulated from the part 9.

The parts 9 and 10 of the heatsink 8 can thus advantageously have a high electrical insulation resistance to one another.

In this embodiment example, the part 10 is sealed against the insulating element 11 by means of a seal 34, in particular an O-ring. In this embodiment example, the part 9 is sealed against the insulating element 11 by means of a seal 35, in particular an O-ring. In another embodiment, the seals 34 and 35 can be injection-molded onto the insulating element 11.

The part 9 comprises a connector 13, in particular a connecting piece, which is fluidically coupled to the cavity 17 and is configured to conduct a fluid flowing in the cavity 17 out of the heatsink 8 and to a fluid pump 18. In this embodiment example, the other part 10 comprises a fluid connector 12, in particular a connecting piece, which is connected to the fluid pump 18 by means of a fluid line 19 and, in this embodiment example, is configured as an inlet of the heatsink 8. Driven by the fluid pump 18, a fluid flow 15 through the cavity 17 and further though the opening 14 into the cavity 16 can be produced, and can thus absorb waste heat from both the inverter 2 and the electric machine 2.

Unlike as shown in FIG. 1, the fluid flow can also be conducted from the machine 2 to the inverter 3 by the fluid pump. In this embodiment example, the electrical contact resistance between the part 9 and the other part 10 of the heatsink is formed by the fluid volume, in particular the cooling water volume, held in the opening 14. The cooling water in this embodiment example is a low mineral cooling water, for example distilled water, or a water-glycol mixture.

The electric machine 2, in particular a housing of the electric machine 2, is electrically connected to a motor mass 20 in this embodiment example. The inverter 3, in particular a housing of the inverter 3, is connected to an inverter ground 21. In this embodiment example, the ground potentials of the grounds 20 and 21 are insulated from one another by means of the electrically insulated heatsink 8, in particular the parts 9 and 10 which are connected to one another in a thermally conductive manner and are electrically insulated from one another. The ground potentials 21 and 20 of the power components, in particular the inverter 3 or the electric machine 2, are thus separated from one another within the heatsink.

In this embodiment example, the power module 1 also comprises a conductance sensor 27, which is connected on the input side to the part 9 by means of a connecting line 28 and to the part 10 by means of a connecting line 29. The conductance sensor is configured to detect an electrical transition conductance formed between the parts 9 and 10 of the heatsink 8 and to produce an output signal representing the conductance.

The fluid is a water-glycol mixture according to a specification SAE J1034, ASTM D 4985, for example, for instance Glysantin® G40 ® or G48®.

In addition to ethylene glycol, the fluid preferably comprises a corrosion inhibitor, in particular a silicate, further preferably a salt of an organic acid.

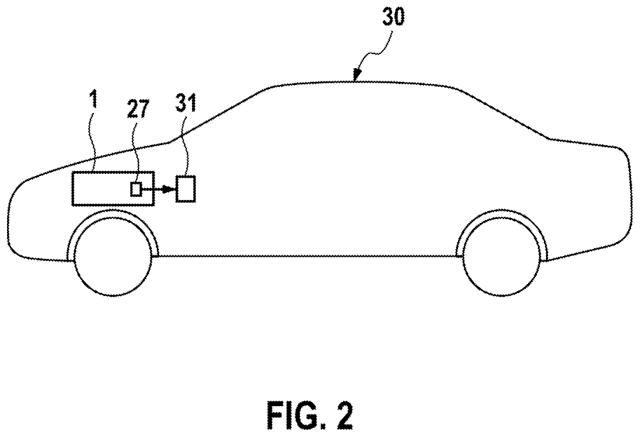

FIG. 2 shows a vehicle, in particular an electric vehicle comprising a power module, in particular the power module 1 shown in FIG. 1. The electric vehicle 30 comprises a control device 31, which is configured to produce an error signal in dependence on the output signal of the conductance sensor 27 when a predetermined conductance is exceeded. When the vehicle is serviced, the conductance of the fluid 15 can be checked in dependence on the error signal and the fluid 15 can be replaced.

1. A power module, comprising:
a heatsink configured to conduct fluid; and
at least two power components which are different from one another and are connected to the heatsink in a thermally conductive and electrically conductive manner,
wherein the power components are each configured to carry differing electrical potentials, and
wherein the heatsink includes at least or only two parts which each comprise a fluid channel formed by a cavity for conducting a fluid flow and are connected to one another by way of an electrical insulator such that a fluid flow cooling both parts can flow through the parts and are electrically insulated from one another such that the electrical potentials of the power components are separated from one another within the heatsink.

2. A power module according to claim 1, wherein the insulator is formed by an electrically insulating element which is contacted by the parts and is enclosed between said parts.

3. A power module according to claim 1, characterized in that wherein:
the parts of the heatsink are each formed by a housing part, and
the housing parts are connected to one another and enclose the insulator between them.

4. A power module according to claim 1, wherein:
the power components are each coupled to a fluid channel in a thermally conductive manner, and
the fluid channels are fluidically connected to one another within the heatsink.

5. A power module according to claim 4, wherein:
one part comprises an inlet for the fluid and the other part comprises an outlet for the fluid, and
the fluid channels are connected to one another by way of a passage in the insulator.

6. A power module according to claim 5, wherein the passage comprises a passage opening, the cross-sectional area of which transverse to a flow direction of the fluid flow is smaller than a contact surface of the parts separated by the insulator.

7. A power module according to claim 1, wherein the insulator is formed by a plastic layer.

8. A power module according to claim 1, wherein the insulator is formed by an insulating element on which at least one pin is formed which encloses the opening and extends into a part of the heatsink, or comprises two pins which each extend into one of the two parts of the heatsink.

9. A power module according to claim 1, wherein the fluid is polar and the power module comprises a conductance sensor which is configured to detect an electrical conductance produced by the fluid between the parts.

10. An electric vehicle or hybrid vehicle comprising a power module according to claim 1, wherein the vehicle comprises an electric machine configured to drive the vehicle and an inverter, wherein one part of the heatsink is electrically connected to the inverter and the other part is electrically connected to the electric machine.

11. The electric vehicle according to claim 9, wherein the part of the heatsink is connected to a ground potential of the inverter and the other part of the heatsink is connected to the ground potential of the electric machine.

12. A power module according to claim 1, wherein the power module is a drive module.

13. A power module according to claim 1, wherein the power components are each configured to carry differing ground potentials.

14. A power module according to claim 1, wherein the insulator is formed by a flat electrically insulating element which is contacted by the parts and is enclosed between said parts.

15. A power module according to claim 1, wherein the housing parts are connected to one another separably, and enclose an insulating layer between them.
